(19) United States
(12) Patent Application Publication
(10) Pub. No.: US 2011/0310582 A1
(43) Pub. Date: Dec. 22, 2011

(54) INFORMATION PROCESSING DEVICE

(75) Inventor: Atsushi Takamatsu, Kanagawa (JP)

(73) Assignee: Sony Corporation, Tokyo (JP)

(21) Appl. No.: 13/160,589

(22) Filed: Jun. 15, 2011

(30) Foreign Application Priority Data
Jun. 22, 2010 (JP) P2010-141255

(51) Int. Cl. H05K 7/02

(52) U.S. Cl. 361/807

(57) ABSTRACT

An information processing device includes: a housing provided with a front panel; an opening provided in the front panel; an opening and closing lid opening and closing the opening; a placing unit, by being provided in the opening and closing lid, being housed within the opening in a state in which the opening and closing lid is closed and allowing a mobile terminal device to be placed in a state in which the opening and closing lid is opened; and a connecting unit provided in the placing unit and connected to the mobile terminal device.

### BACKGROUND

The present disclosure relates to an information processing device, and specifically to an information processing device to which a mobile terminal device is connected and that plays a content stored in the mobile terminal device.

In recent years, mobile terminal devices are becoming popular rapidly that are provided with a storage medium of a large capacity and that can be carried by storing content data, such as music data and video data, in the storage medium. These mobile terminal devices are intended mainly for individuals to enjoy music and the like while traveling or on the road using earphones, headphones, or the like. Accordingly, they are not provided with a speaker in general. Even when provided with a speaker, the volume that can be outputted is low and the speaker is often a monaural speaker, so that the sound quality is not sufficiently satisfactory.

Japanese Unexamined Patent Application Publication No. 2010-60941 proposes an information processing device, a so-called docking station, that is provided with a disc player, a speaker, a high-power amplifier, a tuner circuit, a connecting terminal connectable to a mobile terminal device, and the like and that can play music and the like stored in a mobile terminal device by connecting the mobile terminal device thereto. By using a docking station, music stored in the mobile terminal device can be played from the speaker to enjoy in high sound quality. In addition, unlike earphones that can be used only by an individual, it is also possible to enjoy music with a plurality of persons.

### SUMMARY

In order to obtain a docking station having a high-power amplifier mounted therein as small in size as possible, a digital amplifier is used as the high-power amplifier at present. However, in a case of using a digital amplifier, the entire device is affected by undesirable radiation, so that it is desired to shield the entire docking station with a sheet metal or the like.

When playing music or the like by connecting a mobile terminal device provided with a telephoning function or a network connecting function to such a docking station entirely shielded with a sheet metal, the sheet metal adversely affects the telephone reception characteristics of the mobile terminal device. Therefore, as illustrated in FIG. 1 of Japanese Unexamined Patent Application Publication No. 2010-60941, most docking stations are configured to place a mobile terminal device at a center on the top surface that is good in radio wave characteristics.

The position of connecting a mobile terminal device in a docking station is limited as such, so that the degree of freedom in designing a docking station is very low. In addition, in the docking station to place a mobile terminal device on the top surface, the connecting terminal is normally exposed, so that tiny dusts are attached to the connecting terminal as used for a long period of time. An operation of removing the dusts is a hassle for a user, but not removing them regularly may cause a trouble.

In addition, there is also a problem that a signal for network communication is occasionally sent from a mobile terminal device and the signal affects circuits inside the docking station, a tuner circuit in particular, to generate a noise. With that, due to such problems, a connecting terminal of a mobile terminal device is desired to be disposed at a position spaced apart from the sheet metal, such as an end of the docking station, the tuner circuit, and the like. However, in a case of a configuration having a mobile terminal device simply connected at an end of the docking station, the entire docking station becomes uneven in shape, resulting in losing the design quality and also seriously impairing the merchantability.

Accordingly, it is desirable to provide an information processing device that, even when connected to a mobile terminal device having a telephoning function or the like, does not affect each other and can maintain high design quality.

A device according to an embodiment of the present disclosure is an information processing device including: a housing provided with a front panel; an opening provided in the front panel; an opening and closing lid opening and closing the opening; a placing unit, by being provided in the opening and closing lid, being housed within the opening in a state in which the opening and closing lid is closed and allowing a mobile terminal device to be placed in a state in which the opening and closing lid is opened; and a connecting unit provided in the placing unit and connected to the mobile terminal device.

According to at least one embodiment of the device of the present disclosure, even when connected to a mobile terminal device having a telephoning function, a network connecting function, or the like, the information processing device and the mobile terminal device can be prevented from affecting each other and also the high design quality of the information processing device can be maintained.

### BRIEF DESCRIPTION OF THE DRAWINGS

FIG. 1 is an appearance perspective view illustrating an appearance configuration of an information processing device and a mobile terminal device;

FIG. 2 is a block diagram illustrating a schematic configuration of the information processing device;

FIG. 3 is an appearance perspective view illustrating a state in which an opening and closing lid of the information processing device is closed;

FIG. 4 is a bottom view illustrating a bottom face of the information processing device;

FIG. 5 is a perspective view illustrating an internal configuration of the information processing device;

FIG. 6 is a block diagram illustrating a schematic configuration of the mobile terminal device;

FIG. 7 is a plan view of a terminal device connecting mechanism;

FIG. 8 is a cross-sectional view illustrating a configuration and behaviors of the terminal device connecting mechanism;

FIG. 9 is a cross-sectional view illustrating a configuration and behaviors of the terminal device connecting mechanism;

FIG. 10 is a cross-sectional view illustrating a configuration and behaviors of the terminal device connecting mechanism;

FIG. 11 is a cross-sectional view illustrating a configuration and behaviors of the terminal device connecting mechanism; and

FIG. 12 illustrates a modification of an information processing device.

### DETAILED DESCRIPTION OF EMBODIMENTS

Embodiments of the present disclosure are described below with reference to the drawings. The description is given in the following order.

### <1. Embodiment>

### [1-1. Configuration of Information Processing Device]

### [1-2. Configuration of Mobile Terminal Device]

### [1-3. Configuration of Terminal Device Connecting Mechanism]

### [1-4. Behavior of Terminal Device Connecting Mechanism]

### <2. Modification>

### 1. Embodiment

### 1-1. Configuration of Information Processing Device

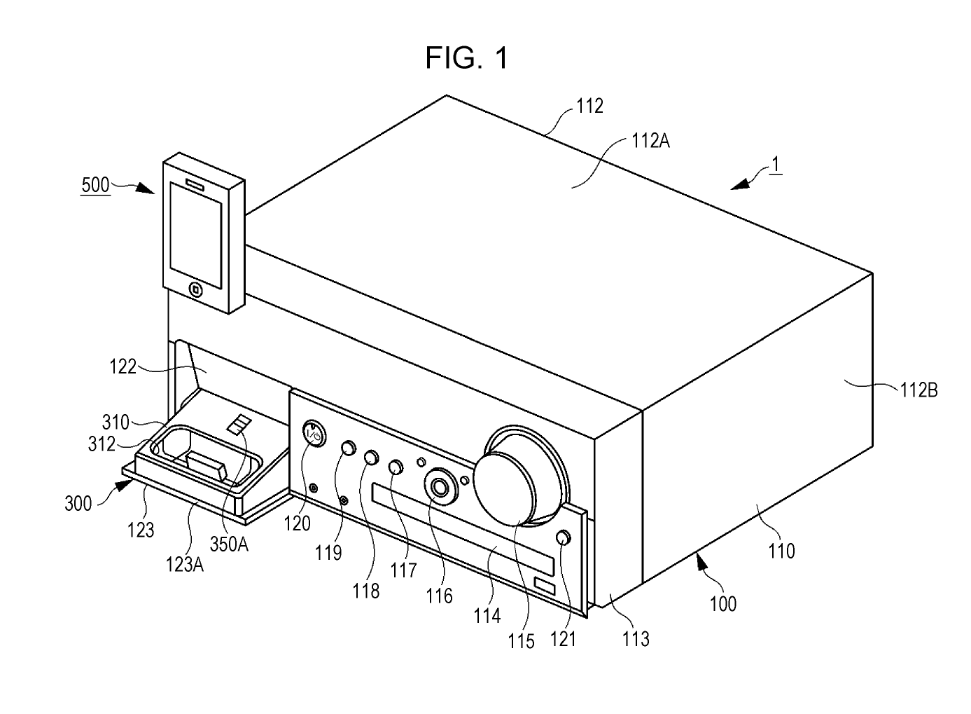

FIG. 1 illustrates an appearance configuration of a docking station as an information processing device 1 and a smartphone as a mobile terminal device 500. The information processing device 1 is connected to the mobile terminal device 500 provided with a telephoning function and a network connecting function. Then, music data stored in the mobile terminal device 500 is transferred to the information processing device 1, and after subjected to a predetermined process, it is outputted from the information processing device 1 to an audio output section (not shown), such as a speaker. Thus, a user can enjoy music stored in the mobile terminal device 500 in high quality.

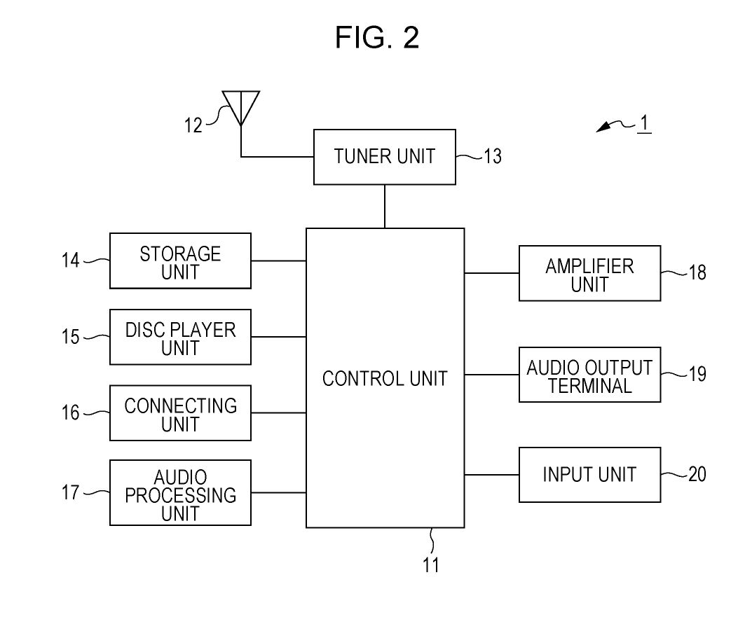

FIG. 2 is illustrates a schematic configuration of the information processing device 1. The information processing device 1 is configured with a control unit 11, a receiving antenna 12, a tuner unit 13, a storage unit 14, a disc player unit 15, a connecting unit 16, an audio processing unit 17, an amplifier unit 18, an audio output terminal 19, and an input unit 20.

The control unit 11 is configured with, for example, a CPU (central processing unit), a RAM (random access memory), and a ROM (read only memory). The ROM stores programs and the like that are read and executed by the CPU. The RAM is used as a working memory for the CPU. The CPU executes a variety of processes in accordance with the programs stored in the ROM to issue commands, thereby controlling the entire information processing device 1.

The tuner unit 13 is a tuner for terrestrial digital radio broadcasting containing a tuning circuit to tune radio waves received by the receiving antenna 12 at a frequency corresponding to a selected receiving channel, a demodulating circuit for a process of signal demodulation, various filtering circuits, and the like. The tuner unit 13 selects a signal for a channel of a channel number specified by a user from high frequency signals for a digital radio received by the receiving antenna 12. Then, the selected high frequency signal is converted to an intermediate frequency signal and the converted signal is subjected to detection, demodulating processes, and the like, thereby obtaining an audio signal to output it to the audio processing unit 17 and the like.

The storage unit 14 is a large capacity storage medium configured with a non-volatile memory and the like. In the storage unit 14, content data, such as music data, image data, and video data, and the like are stored.

The disc player unit 15 reads (plays) music data or the like stored in a disc storage medium (referred to below as a disc), such as a CD (compact disc) and a DVD (digital versatile disc). The disc player unit 15 is configured with a disc tray to place a disc, a rotation driving unit to rotate the disc, an optical pickup to read a signal by irradiating laser light to the disc, a signal processing unit to output it to the audio processing unit 17 by applying a predetermined process to the signal read by the optical pickup, and the like (all not shown).

The connecting unit 16 is a connecting section to connect with the mobile terminal device 500, and for example, is a connecting terminal, such as a 30-pin dock connector. The music data or the like stored in the mobile terminal device 500 is transferred to the information processing device 1 via the connecting unit 16.

The audio processing unit 17 applies a predetermined process, such as a decoding process, to the music data outputted from the disc player unit 15, the music data transferred from the mobile terminal device 500 via the connecting unit 16, or the like to supply it to the amplifier unit 18. The amplifier unit 18 applies an amplification process to the supplied audio signal and outputs it to the audio output terminal 19. The audio output terminal 19 is connected to a speaker (not shown), and the audio processed by the audio processing unit 17, the amplifier unit 18, and the like is finally outputted from the speaker.

The input unit 20 is an input section, such as various buttons and dials, to input volume adjustment, playing/stopping music, and the like to the information processing device 1. When an operation input is made by a user, the input unit 20 generates an operation signal corresponding to the operation to output it to the control unit 11.

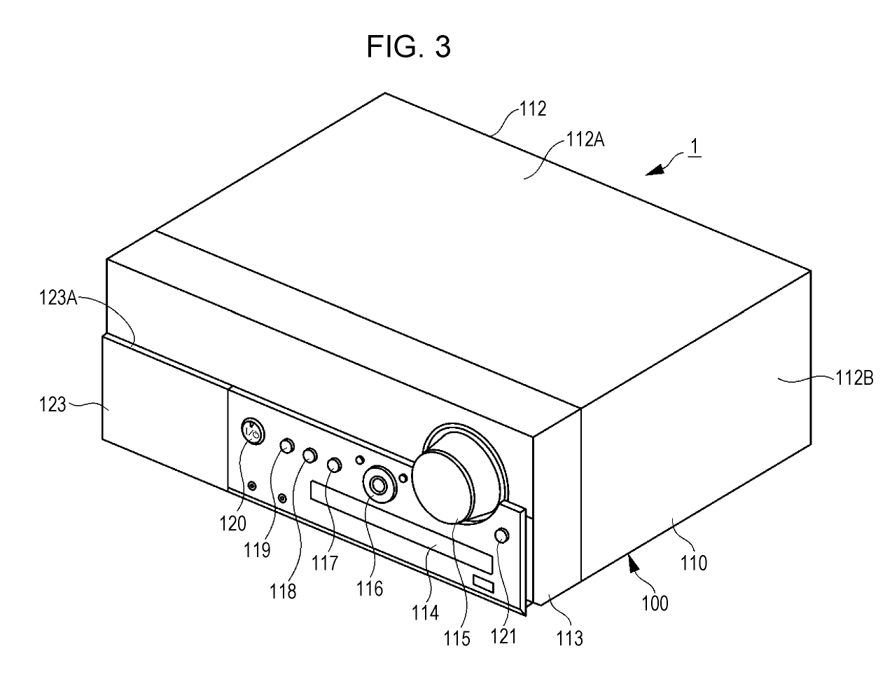

Next, the appearance configuration of the information processing device 1 is described. FIGS. 1, 3, and 4 are appearance perspective views illustrating the appearance configuration of the information processing device 1. FIG. 1 is a state in which an opening and closing lid 123 is opened and FIG. 3 is a state in which the opening and closing lid 123 is closed.

The information processing device 1 is configured with a housing 100, a circuit board 200 accommodated inside the housing 100, and a terminal device connecting mechanism 300 to connect with the mobile terminal device 500.

The housing 100 is configured with a box unit 110, including a chassis 111 and a top panel 112, and a front panel 113. The chassis 111 is formed, for example, using a plate member made of metal, such as aluminum, and is provided with a bottom portion 111A and a back portion 111B configured to stand approximately vertically and upwardly from a rear end of the bottom portion 111A. The circuit board 200 is placed on the chassis 111.

The top panel 112 is formed, for example, using a plate member made of metal, such as aluminum, similar to the chassis 111. The top panel 112 is formed to have a cross section in an approximately U shape with a top portion 112A and a side portion 112B installed approximately vertically and downwardly from both of right and left ends of the top portion 112A. Then, the top panel 112 is provided to cover the chassis 111 and is fixed to the chassis 111 using, for example, a bolt, a nut, and the like (not shown).

The front panel 113 is formed using, for example, a member made of a synthetic resin, such as plastics. The front panel 113 is fixed to the chassis 111 and/or the top panel 112 using a bolt, a nut, and the like (not shown) to be positioned at the front of the information processing device 1.

In the front panel 113, a tray insertion port 114 is formed so as to allow insertion of a disc tray to place a disc, such as a CD and a DVD. In the front panel 113, various buttons, dials, and the like are provided for a user to operate the information processing device 1. A volume dial 115 is a dial to adjust a volume of the music played by the information processing device 1. An operation button 116 is a button to carry out various operations, such as fast forwarding and rewinding of music and tuning of a digital radio. A stop button 117 is a button to stop music being played. A play button 118 is a button to start playing music. In addition, there are provided a function button 119 to call various functions provided in the information processing device 1 and a power button 120 to switch on/off of the power source of the information processing device 1. Further, on the upper right of the tray insertion port 114, an eject button 121 to take the disc tray in and out is provided.

These various buttons and dials are electrically connected to the circuit board 200 provided within the housing 100. When an input is carried out by a user, a control signal corresponding to the input is generated and the control signal is outputted to a main circuit or the like of the circuit board 200. Then, a process corresponding to the control signal is carried out by the main circuit or the like, thereby carrying out a behavior, such as playing/stopping of music and volume adjustment, desired by a user. These buttons and dials are equivalent to the input unit 20 in the block diagram illustrated in FIG. 2.

At a left end in the front view of the front panel 113, an opening 122 is formed. The opening 122 is formed in an approximately quadrangular shape in the front view and also is formed to have a predetermined depth, thereby functioning as a housing unit to house a placing unit 310 configuring a terminal device connecting mechanism 300.

The opening and closing lid 123 is a lid to open and close the opening 122, and similar to the front panel 113, is formed in an approximately flat plate shape using, for example, a member made of a synthetic resin, such as plastics. The opening and closing lid 123 functions as a part of the front panel 113 in a closed state, so that a color and design identical to those of the front panel 113 are applied to its outer surface. An upper end of the opening and closing lid 123 functions as a catching portion 123A that can be caught on a finger or the like by a user. A user catches the catching portion 123A on a finger to pull the opening and closing lid 123, thereby allowed to open the opening and closing lid 123.

In an inner surface of the opening and closing lid 123, a placing unit 310 that configures the terminal device connecting mechanism 300 is provided. The placing unit 310 functions as a table to place the mobile terminal device 500. As illustrated in FIG. 3, the placing unit 310 is housed within the opening 122 in a state in which the opening and closing lid 123 is closed. Then, as illustrated in FIG. 1, the mobile terminal device 500 can be placed in a state in which the opening and closing lid 123 is opened.

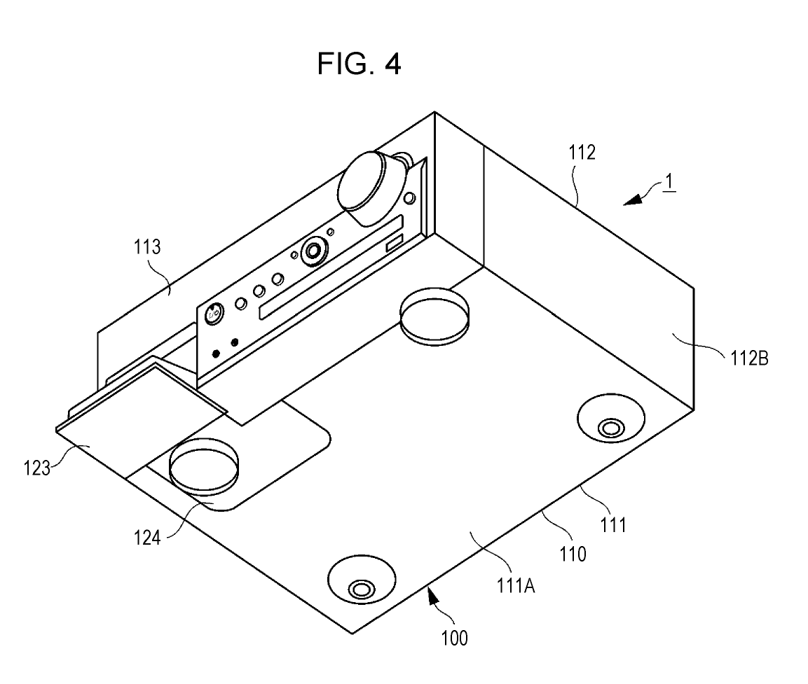

FIG. 4 is a bottom view illustrating a bottom face of the information processing device 1. As described above, the housing 100 is configured with the box unit 110, including the chassis 111 and the top panel 112 made of metal, and the front panel 113 made of a synthetic resin. It should be noted that the chassis 111 has a bottom ground in the vicinity of the terminal device connecting mechanism 300 and is configured to eliminate the presence of a metal plate in the vicinity of the terminal device connecting mechanism 300. Then, at the position, a cover 124 is provided formed using, for example, a synthetic resin, such as plastics, similar to the front panel 113. Thus, it is possible to prevent the metal plate forming the chassis 111 from affecting the telephone reception characteristics of the mobile terminal device 500.

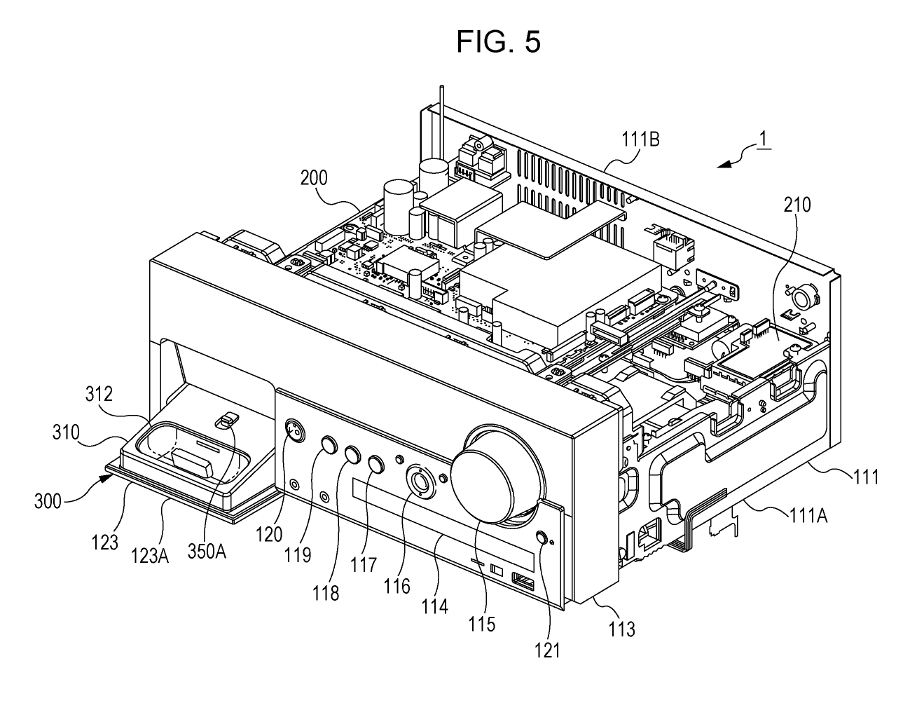

FIG. 5 illustrates an internal configuration of the information processing device 1. The circuit board 200 is provided with a power circuit to control the power supply for the entire information processing device 1 and a main circuit to control behaviors of the entire information processing device 1. There are also provided a carrier control circuit to control entrance and exit of the disc tray, a rotation driving circuit to rotate a disc, and a disc playing processing circuit to read a signal by irradiating laser light to the disc. Further, there are also provided a tuner circuit 210, an audio processing circuit to apply a predetermined process, such as adjustment of an output level or adjustment of frequency characteristics, to the audio signal outputted from the disc playing circuit or the tuner circuit 210, an amplifier circuit to process amplification of the audio signal, and the like. These various circuits are mounted on the circuit board 200 in an electrically connected state.

The main circuit is equivalent to the control unit 11 in the block diagram illustrating the configuration of the information processing device 1 shown in FIG. 2. The carrier control circuit, the rotation driving circuit, and the disc playing processing circuit are equivalent to the disc player unit 15. The tuner circuit 210 is equivalent to the tuner unit 13. Further, the audio processing circuit is equivalent to the audio processing unit 17 and the amplifier circuit is equivalent to the amplifier unit 18.

The tuner circuit 210 is the tuner circuit 210 for terrestrial digital radio broadcasting containing a tuning circuit, in a case of selecting a receiving channel, to tune radio waves received by the receiving antenna 12 at a frequency corresponding to the selected receiving channel, a demodulating circuit to process demodulation of the signal, various filtering circuits, and the like. The tuner circuit 210 selects a signal for a channel of a channel number specified by a user from high frequency signals for a digital radio received by the receiving antenna 12. Then, the selected high frequency signal is converted to an intermediate frequency signal and the converted signal is subjected to detection, demodulating processes, and the like, thereby obtaining an audio signal to output it to the audio processing circuit and the like.

The tuner circuit 210 is, as seen from FIG. 5, provided on the right rear of the chassis 111 when viewing the information processing device 1 from the front. Then, the terminal device connecting mechanism 300 configured with the placing unit 310 and the like is provided on the left front when viewing the information processing device 1 from the front, which is at a position most spaced apart from the tuner circuit 210. This is to space apart the positions of the tuner circuit 210 and the mobile terminal device 500 connected to the terminal device connecting mechanism 300. By spacing apart the tuner circuit 210 and the mobile terminal device 500, it is possible to suppress that the signal for network communication transmitted from the mobile terminal device 500 provided with a network communication function affects the tuner circuit 210 to generate a noise.

### 1-2. Configuration of Mobile Terminal Device

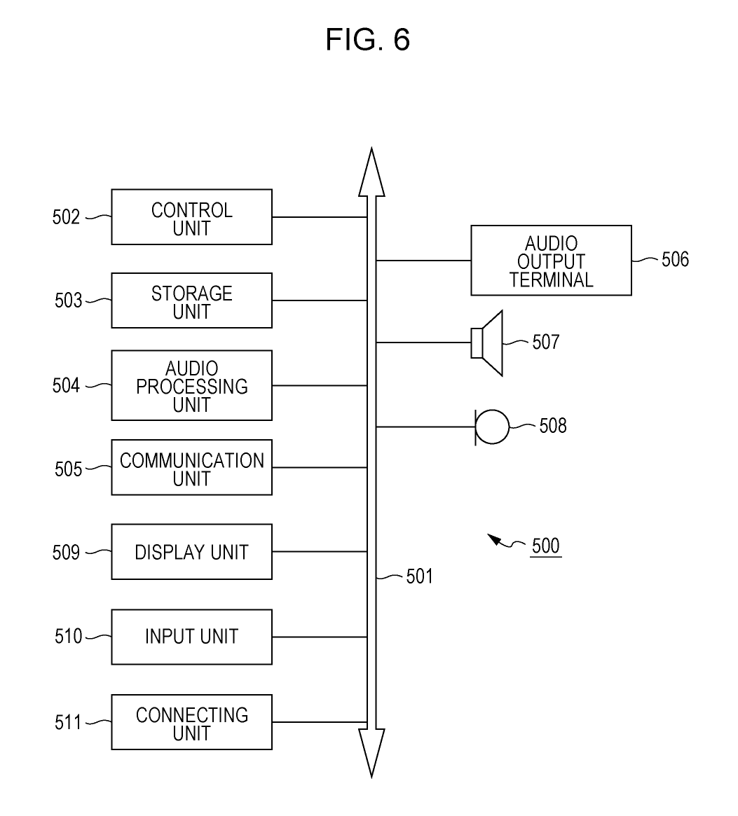

FIG. 6 illustrates a schematic configuration of the mobile terminal device 500. The mobile terminal device 500 is configured with a control unit 502, a storage unit 503, an audio processing unit 504, a communication unit 505, an audio output terminal 506, a speaker 507, a microphone 508, a display unit 509, an input unit 510, and a connecting unit 511 connected via a bus 501. The mobile terminal device 500 is a smartphone or a mobile telephone that can play a content, such as music data, stored in the storage unit 503 and also is provided with a telephoning function and an Internet connecting function.

The control unit 502 is configured with, for example, a CPU, a RAM, and a ROM. The ROM stores programs and the like that are read and executed by the CPU. The RAM is used as a working memory for the CPU. The CPU executes a variety of processes in accordance with the programs stored in the ROM to issue commands, thereby controlling the entire mobile terminal device 500.

The storage unit 503 is a large capacity storage medium configured with a hard disk, a non-volatile memory, or the like. In the storage unit 503, a plurality of content data items, such as music data, image data, and video data, are stored. In addition, various data, such as telephone numbers and email addresses, is also stored. A format of the music data includes, for example, MP3 (MPEG audio layer-3), WAV (RIFF waveform audio format), and AIFF (audio interchange file format). The audio processing unit 504 applies a predetermined process, such as a decoding process, to the music data read from the storage unit 503 by the control unit 502 to supply it to the speaker 507.

The communication unit 505 is a communication module for wireless communication between a nearest base station and the Internet based on, for example, a system, such as a 3G system (a third generation mobile telephone system), or WI-FI (wireless fidelity).

The audio output terminal 506 is a terminal for audio output, such as a 3.5 mm stereo headphone mini-jack, for example. The audio output terminal 506 is connected to headphones, earphones, and the like (not shown). Then, the audio signal outputted from the audio processing unit 504 is finally outputted from the headphones as audio. Thus, it becomes possible for a user to listen to music through headphones or the like.

The speaker 507 is an audio output section to output the audio signal outputted from the audio processing unit 504 as audio such as music, a voice call, or the like. The microphone 508 is an audio input section to input a voice call of a user. The audio inputted to the microphone 508 is converted to a voice call signal and is subjected to a predetermined process by the control unit 502 or the like, and is sent to a mobile terminal device of the other party of the voice call via the communication unit 505.

The display unit 509 is a video display section configured with, for example, an LCD (liquid crystal display), an organic EL (electro luminescence) display, or the like. On the display unit 509, a state of the mobile terminal device 500, various data, soft buttons in a touchscreen, and the like are displayed.

The input unit 510 is an input section, such as a button, a jog dial, a numeric keypad, and a touchscreen, for example, that is used when a user carries out an input to the mobile terminal device 500. When a user makes an operation input, the input unit 510 generates an operation signal corresponding to the operation to output it to the control unit 502.

The connecting unit 511 is a connecting section to connect with the information processing device 1, and for example, is a connecting terminal, such as a 30-pin dock connector.

### 1-3. Configuration of Terminal Device Connecting Mechanism

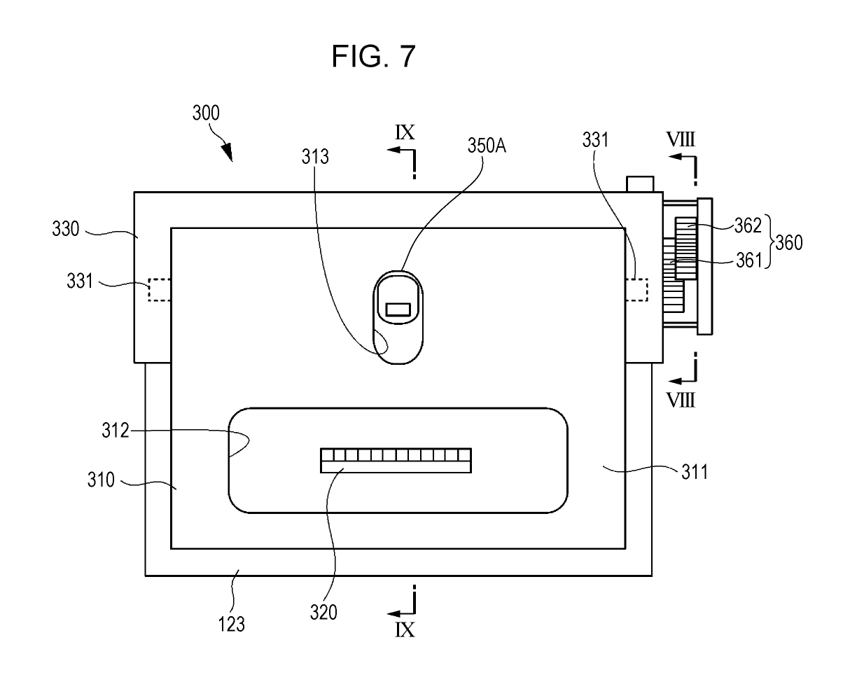

Next, with reference to FIGS. 7 through 11, the configuration of the terminal device connecting mechanism 300 is described. The terminal device connecting mechanism 300 is provided on an inner surface of the opening and closing lid 123, and is configured with the placing unit 310 functioning as a table to place the mobile terminal device 500, a connecting terminal 320 to connect the mobile terminal device 500, a supporting unit 330 to rotatively support the placing unit 310, a lock slider 340 as a locking section to lock the opening and closing lid 123 and the placing unit 310 in an opened state, an unlocking operation body 350 as an unlocking section to release the locking by the lock slider 340, and a gear mechanism 360 to suppress a rotation speed of the placing unit 310.

Each portion configuring the terminal device connecting mechanism 300 described above is formed using, for example, a member made of a synthetic resin, such as plastics. Then, the front panel 113 and the opening and closing lid 123 are also formed using a member made of a synthetic resin similarly. Accordingly, all members in the vicinity of the position of connecting the mobile terminal device 500 are formed using members made of a synthetic resin and a metal plate is not used. Thus, it is possible to suppress that a metal plate affects the telephone reception characteristics of the mobile terminal device 500.

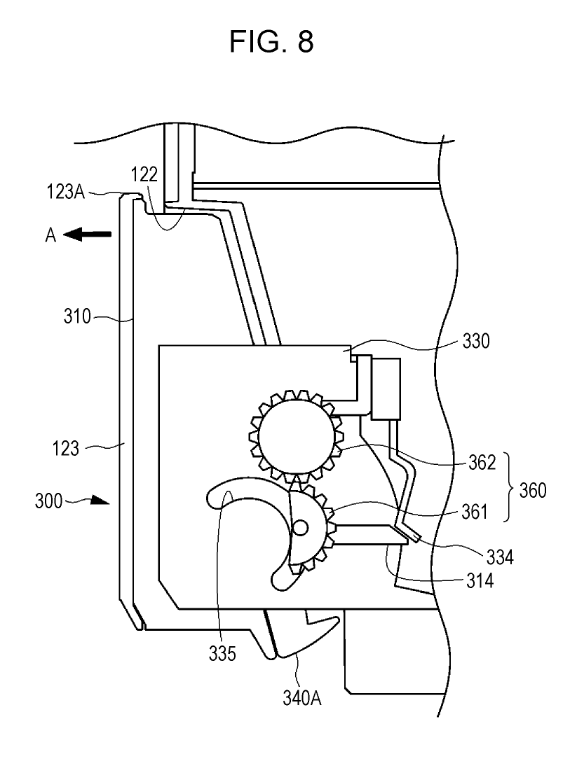

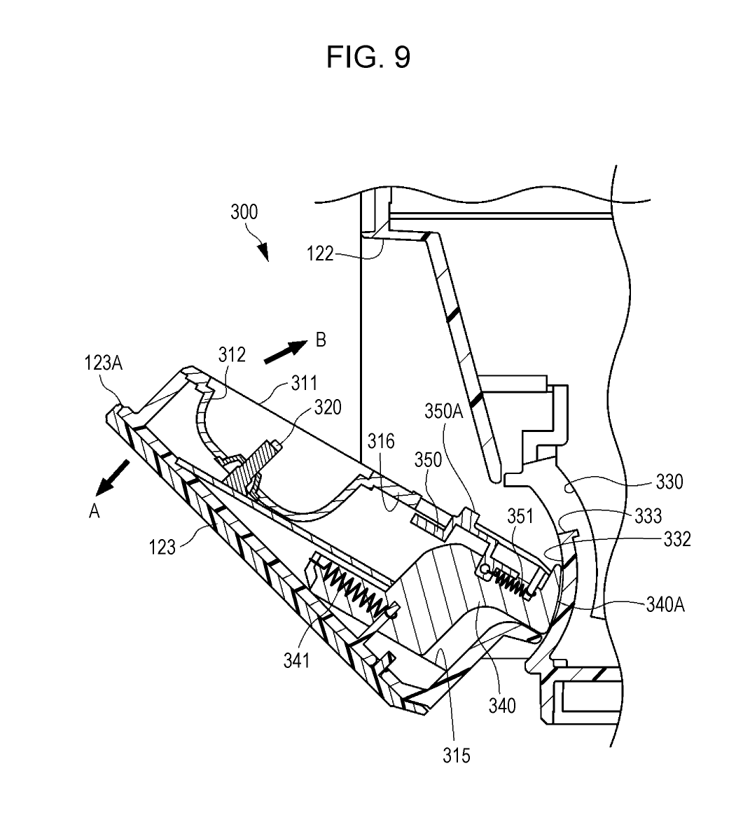

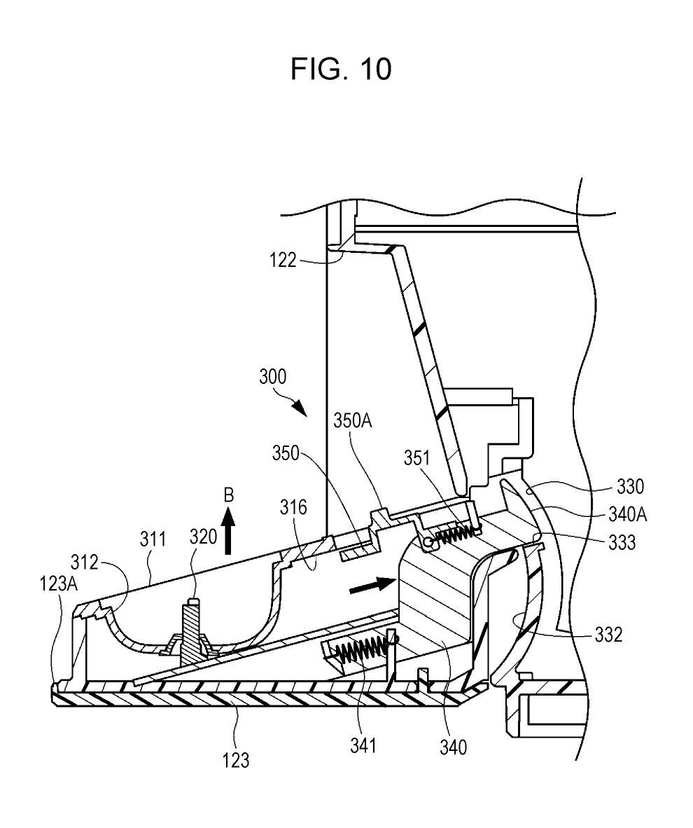

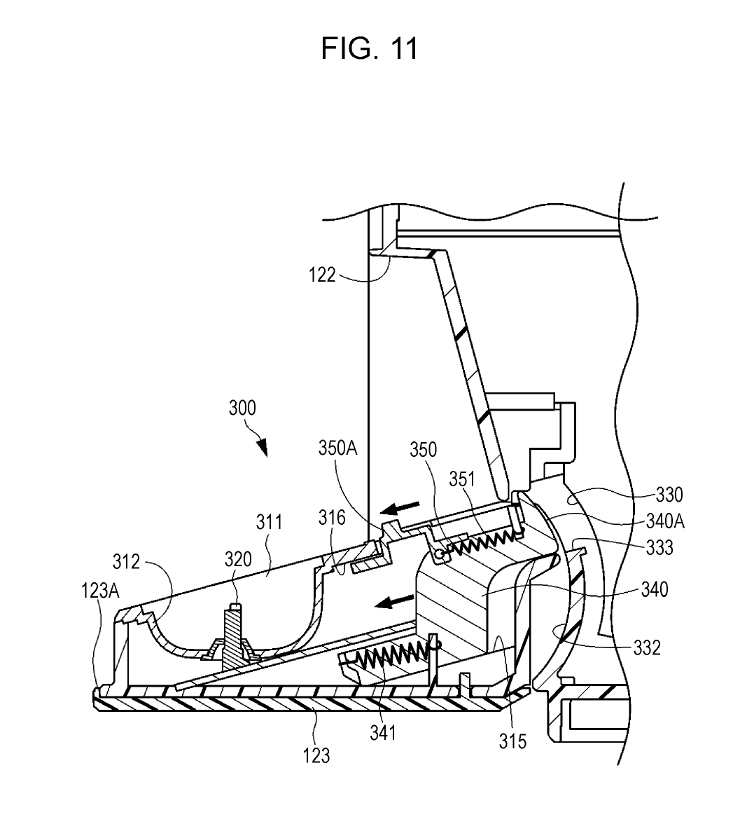

FIG. 7 is a plan view of the terminal device connecting mechanism 300 in a state in which the opening and closing lid 123 is opened. FIGS. 8 through 11 are cross-sectional views illustrating configurations and behaviors of the terminal device connecting mechanism 300. FIG. 8 is a state in which the opening and closing lid 123 is closed and the placing unit 310 is housed. FIG. 9 is a state in which the opening and closing lid 123 and the placing unit 310 are rotating. FIG. 10 is a state in which the opening and closing lid 123 is opened and is locked in the opened state. FIG. 11 is a state in which the terminal device connecting mechanism 300 is unlocked. FIG. 8 is a cross-sectional view of VIII-VIII in FIG. 7. FIGS. 9 through 11 are cross-sectional views of IX-IX in FIG. 7.

The placing unit 310 is formed to have a longitudinal cross section in an approximately trapezoidal shape by inclining an upper face 311. The placing unit 310 is formed with a pocket portion 312 by recessing the front of the upper face 311. Then, at an approximate center of the pocket portion 312, the connecting terminal 320 is provided to be exposed for connection of the mobile terminal device 500. The connecting terminal 320 is equivalent to the connecting unit 16 in the block diagram illustrating the configuration of the information processing device 1 illustrated in FIG. 2. This is also equivalent to a connecting unit in an embodiment of the present disclosure. The connecting terminal 320 is connected to the circuit board 200 provided within the housing 100 using a connecting wire (not shown). The music data and the like stored in the mobile terminal device 500 are transferred to an audio processing circuit (audio processing unit 17) or the like on the circuit board 200 via the connecting terminal 320 and the connecting wire.

At an approximate center of the rear of the upper face 311 (behind the pocket portion 312) of the placing unit 310, an operating projection exposing port 313 is formed to expose an operating projection 350A of the unlocking operation body 350. Further, inside of the placing unit 310 is formed in a hollow shape, and an internal bottom face 315 is a sliding surface for the lock slider 340 described later to slide. An internal upper face 316 is a sliding surface for the unlocking operation body 350 described later to slide.

On one side of the placing unit 310, an engaging piece 314 is provided to support the opening and closing lid 123 in a closed state by engaging with a flat spring 334 of the supporting unit 330 described later.

The supporting unit 330 is to turnably support the placing unit 310 by supporting pivotally using an axis 331. The placing unit 310 is supported by the supporting unit 330 for rotation, thereby rotating the opening and closing lid 123 as well. The supporting unit 330 is fixed to the front panel 113 using, for example, a bolt, a nut, and the like. On back face of the supporting unit 330, there is a sliding curved face 332 that is formed in a curved shape and on which the lock slider 340 slides during rotation of the opening and closing lid 123. Above the sliding curved face 332, a hooking hole 333 is formed to catch a tip end 340A of the lock slider 340. Further, the supporting unit 330 is provided with the flat spring 334 to keep the placing unit 310 and the opening and closing lid 123 in a closed state by catching the engaging piece 314.

The lock slider 340 as a locking section is provided inside the placing unit 310 and is configured to be slidable on the internal bottom face 315 of the placing unit 310. The tip end 340A of the lock slider 340 is configured to project outside the placing unit 310 from a lock slider projection port (not shown) formed on the back face of the placing unit 310. Then, the lock slider 340 is normally biased in a direction of the sliding curved face 332 by a spring 341. The tip end 340A of the lock slider 340 enters into the hooking hole 333 to be caught, thereby suppressing rotation of the placing unit 310 and the opening and closing lid 123 to lock the placing unit 310 and the opening and closing lid 123 in an opened state.

The unlocking operation body 350 as an unlocking section is provided in a state slidable along the internal upper face 316 of the placing unit 310 by being supported by a bolt or the like on the internal upper face 316 of the placing unit 310. It is also normally biased in the direction of the sliding curved face 332 by a spring 351. Then, a projection (not shown) provided in the unlocking operation body 350 engages with a projection (not shown) provided in the lock slider 340, thereby configuring the lock slider 340 to be drawn in a direction of the pocket portion 312 (in an unlocking direction) in coordination with the behavior of the unlocking operation body 350. The lock slider 340 results in behaving only in the direction of the pocket portion 312 (in the unlocking direction) in coordination with the unlocking operation body 350. The lock slider 340 may behave in coordination with a behavior of the unlocking operation body 350, so that it is not limited to the method of engaging with the projections but it may also behave in coordination by adhering, configuring as an integrated component, or the like.

On an upper face of the unlocking operation body 350, the operating projection 350A in a projection shape is formed and the operating projection 350A is exposed from the operating projection exposing port 313 formed in the upper face 311 of the placing unit 310. The operating projection 350A is equivalent to an operation section of an unlocking section in an embodiment of the present disclosure. The unlocking operation body 350 is pulled in a direction opposite to the sliding curved face 332 by catching this operating projection 350A on a finger, thereby drawing the lock slider 340 with the unlocking operation body 350. Then, the drawn lock slider 340 slides in a direction opposite to the sliding curved face 332 and the tip end 340A of the lock slider 340 falls out of the hooking hole 333. Thus, the lock that has suppressed rotation of the placing unit 310 and the opening and closing lid 123 is released.

The gear mechanism 360 is a mechanism to slow the rotation speed of the placing unit 310 and the opening and closing lid 123. The gear mechanism 360 is configured with a first gear 361 provided on one side of the placing unit 310 and a second gear 362 provided in the supporting unit 330 and engaging with the first gear 361. By using, for example, an O ring or the like, minor friction load is applied to a gear shaft of the second gear 362. When the placing unit 310 rotates about the axis 331, rotation of the placing unit 310 is transmitted to the second gear 362 by the first gear 361 to rotate the second gear 362. Then, the friction load is applied to the second gear 362 as described above, so that the rotation speed of the placing unit 310 is slowed down to an appropriate speed by the friction load.

The first gear 361 and the engaging piece 314 are configured integrally. Then, they are mounted to a side of the placing unit 310 with a bolt through a coordination hole 335 formed on a side of the supporting unit 330. The coordination hole 335 is formed in an approximately arc shape along the rotation trajectory in such a manner that the first gear 361 and the engaging piece 314 are rotative in coordination with the rotation of the placing unit 310. In such a manner, the first gear 361 and the engaging piece 314 are configured to rotate in coordination with the rotation of the placing unit 310.

### 1-4. Behavior of Terminal Device Connecting Mechanism

Next, a description is given to behaviors of the terminal device connecting mechanism 300 configured as described above. Firstly, a state in which the opening and closing lid 123 is closed and the placing unit 310 is housed within the opening 122 is described. As illustrated in FIG. 8, in a state in which the opening and closing lid 123 is closed, the engaging piece 314 provided on the side of the placing unit 310 engages with the flat spring 334 provided in the supporting unit 330. Thus, the opening and closing lid 123 is maintained in a closed state and the opening and closing lid 123 is not opened inadvertently.

Then, in a case that a user opens the opening and closing lid 123 to connect with the mobile terminal device 500, the catching portion 123A is caught on a finger or the like to pull in a direction A. When the pulling force exceeds the pressing force of the flat spring 334 to the engaging piece 314, the engaging piece 314 disengages from the flat spring 334 to start rotation of the placing unit 310 in the direction A.

As illustrated in FIG. 9, during rotation, the tip end 340A of the lock slider 340 slides on the sliding curved face 332 while being pressed by the spring 341 in a direction of the sliding curved face 332. Then, when the opening and closing lid 123 is fully opened, the lock slider 340 is biased by the spring 341 in the direction of the sliding curved face 332, so that the lock slider 340 slides in the direction of the sliding curved face 332 as illustrated in FIG. 10 to insert the tip end 340A in the hooking hole 333. The lock slider 340 is normally biased by the spring 341 in the direction of the sliding curved face 332, so that unless the unlocking operation body 350 is operated, the tip end 340A does not fall out of the hooking hole 333. Thus, the hooking hole 333 is caught on the tip end 340A of the lock slider 340 to prevent rotation of the placing unit 310 in a direction B and a lift of the placing unit 310. That is, the position of the placing unit 310 is locked.

In a state in which the opening and closing lid 123 is opened, a user can place the mobile terminal device 500 in the placing unit 310 to connect with the connecting terminal 320. Thus, it becomes possible to transfer music data, stored in the mobile terminal device 500, or the like to the information processing device 1, and the user can enjoy the music stored in the mobile terminal device 500 with the information processing device 1.

In a case of removing the mobile terminal device 500 from the information processing device 1, a user only has to grab the mobile terminal device 500 to lift it upwardly. As described above, the hooking hole 333 is caught on the tip end 340A of the lock slider 340 to prevent a lift of the placing unit 310. Therefore, even when the mobile terminal device 500 is lifted up, the placing unit 310 is not lifted up in coordination with that. Accordingly, a user can remove the mobile terminal device 500 easily with one hand.

Then, after removing the mobile terminal device 500 from the information processing device 1, in a case of closing the opening and closing lid 123, a user firstly puts a finger or the like to catch the operating projection 350A exposed on the upper face 311 of the placing unit 310 and pulls in the direction of the pocket portion 312. That way, the lock slider 340 is configured to behave in coordination with the unlocking operation body 350, so that the lock slider 340 is drawn in the direction of the pocket portion 312. Thus, the tip end 340A of the lock slider 340 falls out of the hooking hole 333 to release the lock to prevent rotation of the opening and closing lid 123. That is, the opening and closing lid 123 and the placing unit 310 are in a rotative state.

The operating projection 350A is provided to be exposed behind the pocket portion 312. Therefore, in a state in which the mobile terminal device 500 is connected to the connecting terminal 320, the operating projection 350A hides behind the mobile terminal device 500 to be untouchable. Thus, it is possible to prevent that, in a state in which the mobile terminal device 500 is connected, the lock is released to close the opening and closing lid 123.

Then, a user rotates the opening and closing lid 123 in the direction B in an unlocked state, thereby enabling the opening and closing lid 123 to be closed. Then, when the opening and closing lid 123 is rotated until becoming in an approximately vertical state, the flat spring 334 is caught on the engaging piece 314 as illustrated in FIG. 8 to maintain the closed state of the opening and closing lid 123.

In such a manner, the opening and closing lid 123 is configured to allow opening and closing by rotation. Then, as illustrated in FIG. 5, the opening and closing lid 123 is configured to be opened towards the front of the information processing device 1. That is, the position of the connecting terminal 320 of the terminal device connecting mechanism 300, that is, the position of the mobile terminal device 500 to be connected is further spaced apart from the tuner circuit 210. Thus, it is possible to suppress that the signal for network communication transmitted from the mobile terminal device 500 affects the tuner circuit 210 to generate a noise.

The opening and closing lid 123 is configured to allow opening and closing by rotation, so that in a case that the mobile terminal device 500 is not connected to the information processing device 1, it can house the placing unit 310. Thus, it is possible to prevent dusts from piling up on the pocket portion 312 of the placing unit 310 and dusts from attaching to the connecting terminal 320. In a case that the mobile terminal device 500 is not connected, by eliminating the presence of the terminal device connecting mechanism 300, it is possible to appeal to users for an appearance shape with integrity and unity.

The opening and closing lid 123 is configured to allow opening and closing by rotation, and in the state in which the opening and closing lid 123 is closed, the placing unit 310 is housed within the opening 122 in a vertically standing state. Thus, it becomes possible to reduce trail avoidance of the opening and closing lid 123 and also to reduce the depth of the housing space in the placing unit 310. Therefore, it is possible to effectively carry out disposition in the housing 100 of the terminal device connecting mechanism 300.

The rotation speed of the opening and closing lid 123 is slowed down to an appropriate speed by the gear mechanism 360, so that it does not happen that, excessively fast rotation makes an impact on the placing unit 310 or the like when the opening and closing lid 123 is fully opened or that excessively slow rotation gives a user a feeling of discomfort.

### 2. Modification

Although a specific description is given above to one embodiment of the present disclosure, embodiments of the present disclosure are not limited to the embodiment described above but various modifications are possible that are based on the technical idea of embodiments of the present disclosure. For example, the positional relationship between the tuner circuit 210 and the terminal device connecting mechanism 300 is not limited to the right rear and the left front as described above. The tuner circuit 210 and the terminal device connecting mechanism 300 may be disposed to be most spaced apart in the housing 100. Accordingly, the tuner circuit 210 may also be disposed on the left rear of the housing 100 when the information processing device 1 is viewed from the front and the terminal device connecting mechanism 300 may also be provided on the right front of the information processing device 1. That is, in a case that the housing 100 is in an approximately rectangular parallelepiped shape, the tuner circuit 210 may be provided at any one of the four corners in the housing 100 and the terminal device connecting mechanism 300 may be provided at a diagonal corner thereof.

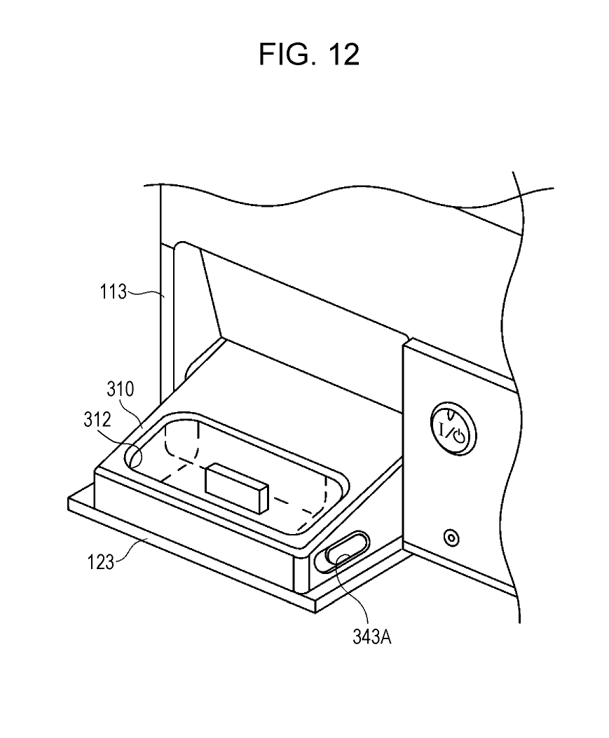

In addition, the position of exposing the operating projection 350A of the unlocking operation body 350 is not limited to the upper face 311 of the placing unit 310. For example, as illustrated in FIG. 12, it may also be provided on a side face of the placing unit 310.

In addition, although a description is given in the embodiment using an exemplified case of transferring music data stored in the mobile terminal device 500 to the information processing device 1 to be played, the content is not limited to music. For example, the information processing device 1 may also be provided with the display unit 509 that can display a video to output an image, a video, and the like stored in the mobile terminal device 500 with the information processing device 1.

The present disclosure contains subject matter related to that disclosed in Japanese Priority Patent Application JP 2010-141255 filed in the Japan Patent Office on Jun. 22, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An information processing device comprising:
a housing provided with a front panel;
an opening provided in the front panel;
an opening and closing lid opening and closing the opening;
a placing unit, by being provided in the opening and closing lid, being housed within the opening in a state in which the opening and closing lid is closed and allowing a mobile terminal device to be placed in a state in which the opening and closing lid is opened; and
a connecting unit provided in the placing unit and connected to the mobile terminal device.

2. The information processing device according to claim 1, wherein
a circuit board is provided within the housing,
the circuit board is provided with a tuner circuit receiving broadcasting, and
the connecting unit is provided at a position spaced apart from the tuner circuit.

3. The information processing device according to claim 1, wherein the opening and closing lid and the placing unit are made of a synthetic resin.

4. The information processing device according to claim 1, wherein the front panel is made of a synthetic resin.

5. The information processing device according to claim 2, wherein the opening and closing lid is configured to be opened in a direction spaced apart from the tuner circuit.

6. The information processing device according to claim 1, wherein
the opening and closing lid is configured to allow opening and closing of the opening by rotation, and
the placing unit is housed within the opening in a standing state in the state in which the opening and closing lid is closed.

7. The information processing device according to claim 1, wherein the mobile terminal device is provided with a telephoning function and/or a network connecting function.

8. The information processing device according to claim 1, further comprising:
a locking section locking the opening and closing lid in the opened state; and
an unlocking section releasing locking by the locking section; wherein
an operation section operating the unlocking section is provided to be exposed behind the connecting unit on an upper face of the placing unit.
